(19) United States
(12) Patent Application Publication
(10) Pub. No.: US 2024/0210804 A1
(43) Pub. Date: Jun. 27, 2024

(54) IMAGE PROJECTION DEVICE

(71) Applicant: LG ELECTRONICS INC., Seoul (KR)

(72) Inventor: Hooyoung SONG, Seoul (KR)

(73) Assignee: LG ELECTRONICS INC., Seoul (KR)

(21) Appl. No.: 18/288,758

(22) PCT Filed: Apr. 29, 2021
(86) PCT No.: PCT/KR2021/005421

§ 371 Date: Oct. 27, 2023

(51) Int. Cl. G03B 21/20

(52) U.S. Cl. CPC G03B 21/2033; G03B 21/2013; G03B 21/208

(57) ABSTRACT

An image projection device can comprise a light source configured to output light corresponding to an image, and an optical system disposed in front of the light source and configured to project the image.

The light source can comprise a substrate comprising a plurality of pixels and a plurality of semiconductor light emitting devices in the plurality of pixels of the substrate, respectively. The substrate can be disposed to be inclined with respect to the optical system, and the semiconductor light emitting device can emit a first condensed light having a first beam angle inclined with respect to the substrate.

### TECHNICAL FIELD

The embodiment relates to an image projection device.

### BACKGROUND ART

An image projection device is a device that enlarges and projects an image, and has recently been widely adopted in various fields.

There are two image projection devices currently in commercial use.

Firstly, it is a liquid crystal display (LCD)-based image projection device that enlarges and projects an image created by light emitted from an optical member passing through liquid crystals arranged in a plurality of pixels of the LCD panel.

Second, it is a digital light processing (DLP)-based image projection device that projects an image created by reflecting light emitted from an optical member by a digital micromirror device (DMD) member composed of a micrometer array.

Conventionally, a lamp has been used as a light source for an optical member, but a helium lamp has the problem of being large in size and generating a lot of heat.

Conventionally, the light generated from the light source of the optical member spreads, making it difficult to obtain condensed light and making it difficult for the light to collimate. The brightness of the image created by the optical system increases due to the condensed light, and the desired image is created from the optical system by the light traveling in parallel, so condensed light is necessary.

To solve this problem, as shown in FIG. 1A, a Fresnel lens 2 is disposed in front of the lamp light source 1 in the optical member, so that the light spread from the lamp light source 1 is condensed by the Fresnel lens 2 and travels in parallel. However, since the Fresnel lens 2 is disposed in front of the lamp light source 1, there is a problem that the size of the optical member increases and the unit cost of the optical member increases.

In addition, as shown in FIG. 1B, a parabolic reflector 4 is arranged in the optical member to surround a lamp light source (3), so that the light generated from the lamp light source 3 is reflected by the parabolic reflector 4 to obtain condensed light, and the condensed light proceeds in parallel. However, since the parabolic reflector 4 is arranged to surround the lamp light source 3, there is a problem that the size and thickness of the optical member increases and the unit cost of the optical member increases.

Meanwhile, conventionally, an optical system must create an image using light transmitted from a light source, so the optical system must be equipped with numerous mirrors or lenses to create an image. Therefore, the conventional optical system has a problem of having a very complex structure and being bulky.

Recently, the image projection device is widely used as a portable device and must be light and small in size. In particular, a HUD (Head-Up Display) is in the spotlight. It can be installed in a specific area of the car and display the image on the outside display device or windshield. However, because the specific area is narrow, the volume of the image projection device needs to be small in order to be installed in this narrow area.

### DISCLOSURE

### Technical Problem

An object of the embodiment is to solve the foregoing and other problems.

Another object of the embodiment is to provide an image projection device capable of obtaining condensed light from a light source.

Another object of the embodiment is to provide an image projection device capable of obtaining light traveling parallel to the light source.

Another object of the embodiment is to provide an image projection device capable of obtaining an image to be displayed in front from a light source.

Another object of the embodiment is to provide an image projection device capable of reducing the size.

Another object of the embodiment is to provide an image projection device with a simple configuration.

### Technical Solution

According to aspects of the embodiment to achieve the above or other purposes, an image projection device, comprising: a light source configured to output light corresponding to an image; and an optical system disposed in front of the light source and configured to project the image, wherein the light source comprises: a substrate comprising a plurality of pixels; and a plurality of semiconductor light emitting devices in the plurality of pixels of the substrate, respectively, wherein the substrate is disposed to be inclined with respect to the optical system, and wherein the semiconductor light emitting device is configured to emit a first condensed light having a first beam angle inclined with respect to the substrate.

The light source can comprise an electrode disposed on the substrate and spaced apart from the semiconductor light emitting device.

The semiconductor light emitting device can have an isosceles triangle with an apex angle of 90 to 150 degrees adjacent to the electrode.

The light source can comprise a lens surrounding the semiconductor light emitting device, and the lens can emit a second condensed light having a second beam angle inclined with respect to the substrate.

### Advantageous Effects

The effects of the image projection device according to the embodiment are described as follows.

In an embodiment, the light source of the image projection device can comprise a semiconductor light emitting device. In the image projection device, the light source is very important because it determines the luminance, the contrast ratio, and the color gamut of the image. Since a conventional light source uses a lamp, high-temperature heat is generated when used for a long time, so a separate cooling device must be provided to cool the high-temperature heat. In addition, the wavelength of the lamp's light changes due to high temperature, making it difficult to produce the desired image.

In contrast, in the embodiment, an image can be generated and projected using light generated from a semiconductor light emitting device. The semiconductor light emitting device does not generate a lot of heat even when used for a long time, so it can produce high-quality images without wavelength shift. Additionally, since the semiconductor light emitting device can be used semi-permanently, it has the advantage of extending the lifespan of the image projection device. In addition, the semiconductor light emitting device can implement desired colors and achieves excellent color gamut. In addition, the semiconductor light emitting device is very light, so the weight of the image projection device can be dramatically reduced.

In an embodiment, the light source can directly generate a color image by selectively emitting light from a plurality of semiconductor light emitting devices. The conventional light source only generates light of a single wavelength, and a desired image can be generated in an optical system using the light of a single wavelength generated by the conventional light source. Since image must be generated in an optical system, various mirrors or lenses are required in the optical system, making the optical system complex, bulky, and heavy. In contrast, in the embodiment, since a color image is generated directly from a light source, only an optical system that has the function of projecting this color image is needed, so the optical system has a very simple structure, and is light, and small in volume. In addition, in the conventional image projection device, red light, green light, and blue light are generated by separating or reflecting light in an optical system, and in the process of mixing these color lights to create a color image, the color reproduction rate deteriorates, making it difficult to obtain the desired color image. In contrast, in the embodiment, a color image is generated directly from a light source, so it is possible to implement a color image with excellent color gamut.

In an embodiment, a high-brightness image can be projected by emitting the condensed light having a dense beam angle in a specific direction from a light source, thereby obtaining a color image with a high contrast ratio. In this way, since the condensed light is emitted directly from the light source, a separate device to increase luminance is not required, thereby reducing volume, weight, and cost.

In an embodiment, since the light collected from the light source proceeds in parallel to the optical system, there is no need to provide a lens between the light source and the optical system to allow the light to proceed in parallel, thereby reducing volume, weight, and cost.

In embodiments, the light source can be arranged to tilt the substrate relative to the optical system, thereby reducing the area occupied by the substrate. Thus, the volume of the image projection device can be reduced.

In an embodiment, since light corresponding to a color image is emitted directly from a light source, an optical system that comprises only a lens that projects (or expands) the color image can be provided, thereby dramatically reducing the volume and weight of the optical system.

A further scope of applicability of the embodiment will become apparent from the detailed description that follows. However, since various changes and modifications within the spirit and scope of the embodiment can be clearly understood by those skilled in the art, it should be understood that the detailed description and specific embodiment, such as preferred embodiment, are given by way of example only.

### DESCRIPTION OF DRAWINGS

FIG. 1 illustrates a conventional optical element.

FIG. 2 illustrates an image projection device according to a first embodiment.

FIG. 3 is a cross-sectional view illustrating the light source of FIG. 2.

FIG. 4 is an enlarged view illustrating area A of FIG. 3.

FIG. 5 illustrates the arrangement relationship between the substrate and the optical system and the progress path of the condensed light between the substrate and the optical system.

FIG. 6A is a perspective view illustrating a semiconductor light emitting device.

FIG. 6B is a plan view illustrating a semiconductor light emitting device.

FIG. 7 illustrates the arrangement relationship between the electrode and the semiconductor light emitting device.

FIG. 8 illustrates the light intensity depending on the light measurement angle.

FIGS. 9 to 14 illustrate light distribution according to the shape of the semiconductor light emitting device.

FIG. 15 illustrates an image projection device according to a second embodiment.

FIG. 16 is a plan view illustrating a semiconductor light emitting device and a lens.

FIG. 17 illustrates the arrangement relationship between the electrode and the semiconductor light emitting element.

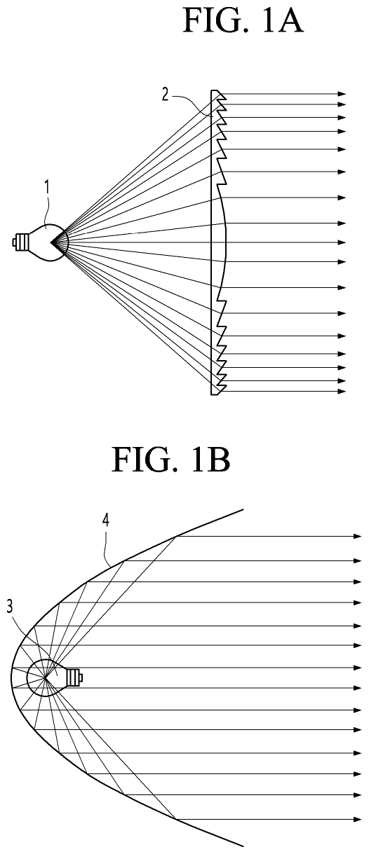

### MODE FOR INVENTION

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there can be directly on the other element or be other intermediate elements therebetween.

By using a light source that emits condensed light, the embodiment can provide an image projection device that does not require a separate device for condensed light, thereby reducing volume, weight, and cost. It is also possible to compact the image projection device.

The embodiment can provide an image projection device capable of securing high brightness and high quality image quality by the condensed light.

The embodiment can provide an image projection device that can emits color light corresponding to an image such that since there is no need for existing members such as numerous mirrors or lenses to create an image using light of a single wavelength, volume, weight, and cost can be reduced.

In this way, by reducing the number of parts, it is possible to simplify the structure and compact the image projection device with a reduced size.

Hereinafter, an image projection device will be described with reference to various embodiments.

### The First Embodiment

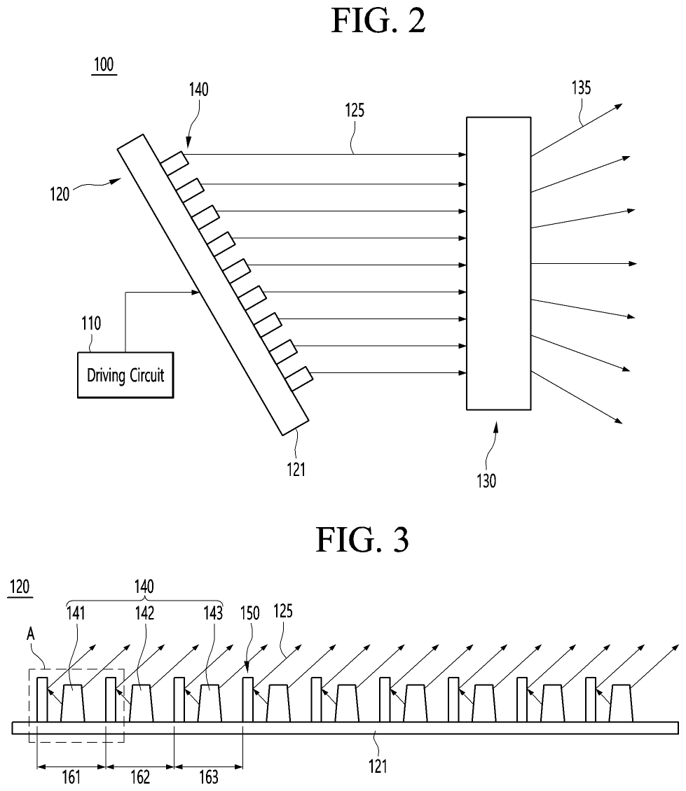

FIG. 2 illustrates an image projection device according to a first embodiment.

Referring to FIG. 2, the image projection device 100 according to the first embodiment can comprise a driving circuit 110, a light source 120, and an optical system 130. More elements can be provided.

The driving circuit 110 can generate a driving signal to emit light corresponding to an image. For example, although not shown, the driving circuit 110 can comprise a red driving circuit, a green driving circuit, and a blue driving circuit. The red driving circuit can generate a red driving signal to emit red light corresponding to a red image. The green driving circuit can generate a green driving signal to emit green light corresponding to a green image. The blue driving circuit can generate a blue driving signal to emit blue light corresponding to a blue image.

For example, the red driving signal, the green driving signal, and the blue driving signal can be supplied to the light source 120 according to the scanning method, so that colored light corresponding to the image can be emitted by the light source 120.

The light source 120 can emit color light corresponding to the image. To this end, the light source 120 can comprise a plurality of pixels (161 to 163 in FIG. 3) each emitting colored light. The plurality of pixels 161 to 163 can be arranged in a matrix, for example, but is not limited thereto.

The light source 120 can comprise, for example, a plurality of semiconductor light emitting devices 140. The semiconductor light emitting device 140 can be made of an inorganic semiconductor material. For example, the semiconductor light emitting device 140 can be made of a group 2-6 compound semiconductor material or a group 3-5 compound semiconductor material, but is not limited thereto.

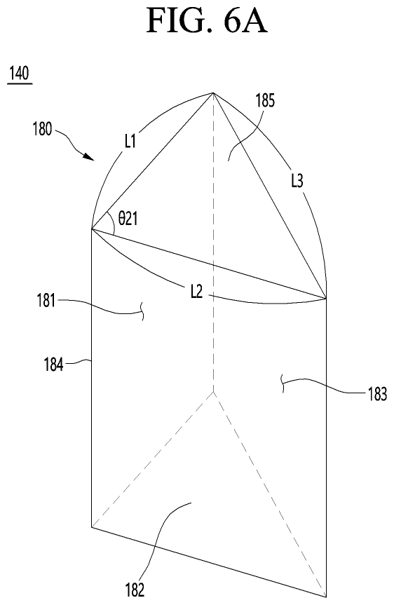

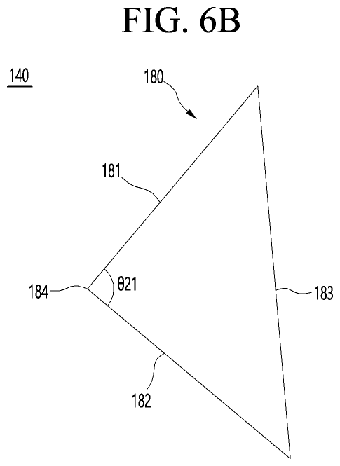

The semiconductor light emitting device 140 of the embodiment can have side surfaces 181 to 183 each having an area greater than the area of an upper surface (185 in FIG. 6A). For example, when the semiconductor light emitting device 140 is miniaturized and the diameter of the semiconductor light emitting device 140 becomes smaller than the height of the semiconductor light emitting device 140, the side surfaces 181 to 183 having an area greater than the area of the upper surface 185 is possible. The semiconductor light emitting device 140 of the embodiment can be a micro-level or nano-level semiconductor light emitting device. The semiconductor light emitting device 140 of the embodiment can comprise, for example, a micro light emitting device, a nano rod light emitting device, a cylindrical light emitting device, a plate type light emitting device, etc.

The semiconductor light emitting device 140 of the embodiment can have a millimeter-scale or centimeter-scale size. Accordingly, the light source 120 of the embodiment can have a millimeter-scale or centimeter-scale size containing hundreds of thousands to millions of semiconductor light emitting devices.

The semiconductor light emitting device 140 can be disposed in each of the plurality of pixels 161 to 163 of the light source 120. For example, the semiconductor light emitting device 140 can comprise a red light emitting device that emits red light, a green light emitting device that emits green light, and a blue light emitting device that emits blue light.

For example, when adjacent first pixels 161, second pixels 162, and third pixels 163 are provided, a red light emitting device can be disposed in the first pixel 161, a green light emitting device can be disposed in the second pixel 162, and a blue light emitting device can be disposed in the third pixel 163. Therefore, an image can be implemented by red light, green light, and blue light emitted from the first to third pixels 161 to 163, respectively.

Meanwhile, each of the plurality of semiconductor light emitting devices 140 of the light source 120 can emit condensed light 125 having a specific beam angle (θ11 in FIG. 5). Here, the condensed light 125 having a specific beam angle θ11 can mean light with a dense distribution of light in a specific direction.

Typically, semiconductor light emitting devices can emit light in all directions. Accordingly, light emitted in all directions can have an approximately uniform light distribution, although there can be some deviation. Since the light is emitted in all directions in this way, the reaching distance of the light is very short, and the amount of light reaching the optical system 130 is small, making it difficult to create a spherical brightness image.

To solve this problem, the plurality of semiconductor light emitting devices 140 of the light source 120 of the embodiment can change the structure to emit the condensed light 125 at a specific beam angle θ11. Here, the specific beam angle θ11 can be a direction perpendicular to the optical system 130. For example, the condensed light 125 can have a beam angle θ11 in a specific direction. Accordingly, the condensed light 125 can be emitted from the semiconductor light emitting device 140 around the beam angle θ11.

For example, the substrate 121 of the light source 120 can be disposed to be inclined with respect to the optical system 130. At this time, the substrate 121 can be arranged to be inclined with respect to the optical system 130 in consideration of the direction of the condensed light 125 emitted from the semiconductor light emitting device 140.

For example, as shown in FIG. 5, when the condensed light 125 is emitted at a specific beam angle θ11 so as to be incident at an angle θ12 perpendicular to the optical system 130, the substrate 121 can be arranged to be inclined at a specific angle with respect to the optical system 130. At this time, the specific angle can be equal to the specific beam angle θ11 of the condensed light 125. In this case, the condensed light 125 emitted from each of the plurality of semiconductor light emitting devices 140 of the light source 120 can be perpendicularly incident on the optical system 130. Light incident perpendicularly to the optical system 130 can be projected as projection light 135 by the optical system 130 to display an image in front, for example, on a screen. The projection light 135 can be light in which the image implemented by the condensed light 125 of the light source 120 is expanded. Since the projection light has luminance and color for each pixel 161 to 163, it can be displayed as a color image on a screen, etc.

The inclination angle of the substrate 121 with respect to the optical system 130 can be, for example, 40 degrees to 140 degrees. For example, if the inclination angle of the substrate 121 with respect to the optical system 130 is less than 50 degrees or more than 140 degrees, it is difficult for the condensed light 125 to be emitted because it is obstructed by the electrode (150 in FIG. 3). For example, w % ben the inclination angle of the substrate 121 with respect to the optical system 130 is 90 degrees, the substrate 121 can be arranged parallel to the optical system 130, and in this case, condensed light 125 can be emitted from the upper side of each semiconductor light emitting device 140.

According to the embodiment, by emitting color light corresponding to the image from the light source 120, there is no need for existing members such as numerous mirrors or lenses to create an image using light of a single wavelength, thereby reducing the size, weight, and cost.

In an embodiment, the condensed light 125 can be emitted from each of the plurality of semiconductor light emitting devices 140 of the light source 120, so that the condensed light 125 can be directly transmitted to the optical system 130. Thus, it can be projected as a high-brightness image, so that a high-contrast color image can be obtained. In this way, since the condensed light 125 is emitted directly from the light source 120, a separate device for increasing luminance is not required, thereby reducing volume, weight, and cost.

In an embodiment, the condensed light 125 emitted from each of the plurality of semiconductor light emitting devices 140 of the light source 120 can be transmitted to the optical system 130 in parallel with each other, so that there is no need to provide a lens that allows light to travel in parallel between the light source 120 and the optical system 130, thereby reducing volume, weight, and cost.

Meanwhile, the optical system 130 can be disposed in front of the light source 120 and can project the condensed light 125 corresponding to the image provided from the light source 120 forward. For example, the optical system 130 can comprise an expansion lens. The condensed light 125 corresponding to the image can be expanded by the optical system 130 by the plurality of semiconductor light emitting devices 140 of the light source 120, so that the expanded image can be displayed in front. The expansion lens can be called a projection lens, a projected lens, a adjustment lens, etc.

Although not shown, the optical system 130 can comprise a focus variable lens that can change focus depending on the position at which the image is displayed in front.

According to the embodiment, the optical system 130 can comprise only an expansion lens. Thus, the volume, weight, and cost can be reduced by eliminating the need for members such as numerous mirrors or lenses, which were required to generate color images using light of a single wavelength.

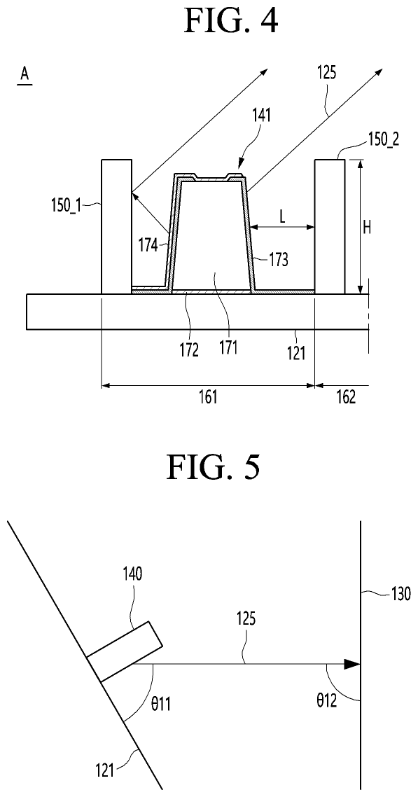

FIG. 3 is a cross-sectional view illustrating the light source of FIG. 2. FIG. 4 is an enlarged view illustrating area A of FIG. 3.

Referring to FIGS. 3 and 4, the light source 120 can comprise a plurality of pixels 161 to 163. Additionally, the light source 120 can comprise a substrate 121 and a plurality of semiconductor light emitting devices 140.

The substrate 121 can be responsible for overall support. The substrate can be made of a material with excellent strength. For example, the substrate 121 can be made of plastic material, ceramic material, sapphire material, non-conductive inorganic material, etc.

A plurality of semiconductor light emitting devices 140 can be disposed on the substrate 121. For example, a semiconductor light emitting device 140 can be disposed in each of the plurality of pixels 161 to 163 of the substrate 121. Although not shown, a signal line is installed on the substrate 121, and the signal line can be electrically connected to each of the semiconductor light emitting devices 140. Each of the semiconductor light emitting devices 140 can emit light by the power supplied to this signal line.

Although not shown, a plurality of scan lines and a plurality of data lines can be intersected and disposed on the substrate 121. A plurality of pixels 161 to 163 can be defined by the intersection of a plurality of scan lines and a plurality of data lines.

A thin-film transistor can be installed at the intersection of the scan line and the data line. The thin film transistor can be electrically connected to the scan line, data line, and semiconductor light emitting device 140.

Since the thin film transistor is turned on by the scan signal supplied by the scan line, the pixels 161 to 163 to display the image can be selected by the scan signal. The data signal supplied by the data line can be transmitted to the semiconductor light emitting device 140 via the turned-on thin film transistor, and the semiconductor light emitting device 140 can emit light by the data signal. The current flowing through the semiconductor light emitting device 140 can be determined by the intensity of the data signal, and the light intensity, that is, the brightness of the image, can be determined by this current.

For example, the substrate 121 can comprise first to third pixels 161 to 163 to implement a color image. The first to third pixels 161 to 163 can be located adjacent to each other. For example, the first to third pixels 161 to 163 can be located side by side along one direction, but this is not limited. That is, the second pixel 162 can be located in contact with the first pixel 161, and the third pixel 163 can be located in contact with the second pixel 162, but this is not limited. A red semiconductor light emitting device 141 that emits red light can be disposed in the first pixel 161, a green semiconductor light emitting device 142 that emits green light can be disposed in the second pixel 162, and a blue semiconductor light emitting device 143 that emits blue light can be disposed in the third pixel 163.

For example, the red semiconductor light emitting device 141 can be made of a compound semiconductor material having a red wavelength band corresponding to red light. For example, the green semiconductor light emitting device 142 can be made of a compound semiconductor material having a green wavelength band corresponding to green light. For example, the blue semiconductor light emitting device 143 can be made of a compound semiconductor material having a blue wavelength band corresponding to blue light.

Meanwhile, each of the plurality of semiconductor light emitting devices 140 can emit condensed light 125 having a beam angle in a specific direction.

Typically, the semiconductor light emitting device can emit light in all directions. In contrast, the semiconductor light emitting device of the embodiment can emit condensed light 125 having a beam angle with dense light distribution in a specific direction by changing its shape. That is, light having a relatively strong intensity and/or a large amount of light, that is, condensed light 125, can be emitted in a specific direction of the light emitting element compared to other directions of the light emitting element.

For example, as shown in FIGS. 3 and 4, the condensed light 125 can be emitted in a direction between a direction parallel to the substrate 121 and a direction perpendicular to the substrate 121, for example, in a diagonal or oblique direction.

For example, the condensed light 125 can be emitted through one side surface (183 in FIG. 6A) of the semiconductor light emitting device 140. For example, the condensed light 125 can be emitted through the upper surface 185 of the semiconductor light emitting device 140. For example, the condensed light 125 can be emitted from the other side surface 81, 182 of the semiconductor light emitting device 140 and then reflected by the electrode 150 and emitted at a specific beam angle θ11.

As shown in FIG. 4, the upper side of the semiconductor light emitting device 140 can be smaller than the lower side. That is, the side surface (181 to 183 in FIG. 6A) of the semiconductor light emitting device 140 can have an inclined surface inclined with respect to the substrate 121. In contrast, the sizes of the lower side and the upper side of the semiconductor light emitting device 140 can be the same. That is, the side surfaces 181 to 183 of the semiconductor light emitting device 140 can have a perpendicular plane perpendicular to the substrate 121.

The specific beam angle θ11 can be, for example, a direction perpendicular to the optical system 130. When the emission direction of the semiconductor light emitting device 140 is determined, the inclination angle of the substrate 121 can be adjusted so that a specific beam angle θ11 can be located in a direction perpendicular to the optical system 130. That is, by adjusting the inclination angle of the substrate 121 disposed to be inclined with respect to the optical system 130, the specific beam angle θ11 at which the condensed light 125 is emitted from the semiconductor light emitting device 140 installed on the substrate 121 can be a direction perpendicular to the optical system 130.

For example, the emission direction of the light 125 emitted from each of the plurality of semiconductor light emitting devices 140 installed on the substrate 121 can be the same or parallel to each other. Accordingly, in the embodiment, the condensed light 125 emitted from each of the semiconductor light emitting devices 140 can travel in parallel with each other, so that since there is no need for a separate lens to propagate light in parallel, the volume and weight can be reduced and the structure can be simplified.

Meanwhile, the light source 120 can comprise a plurality of electrodes 150. Each of the electrodes 150 can be disposed in the pixels 161 to 163 and electrically connected to the semiconductor light emitting device 140. Additionally, the electrode 150 can be electrically connected to a signal line installed on the substrate 121.

The electrode 150 can be disposed to be horizontally spaced apart from the semiconductor light emitting device 140.

For example, the electrode 150 can be an anode electrode. In this case, the electrode 172 shown in FIG. 4 can be a cathode electrode.

The electrode 150 can be a reflective electrode. In this case, light emitted through the side surface (183 in FIG. 6A) of the semiconductor light emitting device 140 can be reflected in a specific direction. The condensed light 125 can be generated with a beam angle in which light distribution is denser in a specific direction compared to other directions by light emitted through the other side 181 and 182 of the semiconductor light emitting device 140 and light reflected by the electrode 150.

As shown in FIG. 4, the semiconductor light emitting device 140 can comprise a light emitting structure 171. For example, the light emitting structure 171 can comprise a first conductivity type semiconductor layer comprising a first conductivity type dopant, an active layer, and a second conductivity type semiconductor layer comprising a second conductivity type dopant. For example, the first conductivity type dopant can be a p-type dopant, and the second conductivity type dopant can be an n-type dopant, but this is not limited.

Although the semiconductor light emitting device 140 of the embodiment illustrates a vertical type semiconductor light emitting device, it is not limited thereto. That is, the semiconductor light emitting device 140 of the embodiment can be a flip chip type semiconductor light emitting device or a horizontal type semiconductor light emitting device.

The electrode 172 can be disposed on an upper side of the semiconductor light emitting device 140. For example, the electrode 150 can be called a first electrode and the electrode 172 can be called a second electrode, but the opposite naming is also possible. For example, the first electrode 150 can be an anode electrode and the second electrode can be a cathode electrode, but the reverse is also possible.

The electrode 172 can be a bonding electrode that has excellent bonding strength with the signal line installed on the substrate 121. The electrode 172 can be a single layer or a multi-layer. For example, the electrode 172 can be included in the semiconductor light emitting device 140, or can be a separate component from the semiconductor light emitting device 140.

Light can be generated in the active layer of the light emitting structure 171 by the power supplied to the electrodes 150 and 172. Light generated in the active layer of the light emitting structure 171 can be emitted as condensed light 125 having a specific beam angle θ11 by changing the shape of the semiconductor light emitting device 140. In addition, the intensity of the condensed light 125 can be further increased by the light reflected by the electrode 150, so that the luminance of the image created by the light source 120 can be further improved.

Meanwhile, the light source 120 can comprise an insulating layer 173. The insulating layer 173 can surround the semiconductor light emitting device 140, that is, the light emitting structure 171. The insulating layer 173 can prevent electrical short circuit of the light emitting structure 171. The insulating layer 173 can be made of an inorganic insulating material. For example, the insulating layer 173 can be made of a silicon oxide-based (SiOx) material or a silicon nitride-based (SiNx) material.

The insulating layer 173 can be disposed on the surface of the substrate 121 as well as the light emitting structure 171. Electrical short circuits in signal lines installed on the substrate 121 can be prevented by the insulating layer 173. Additionally, since the insulating layer 173 can extend from the side surface of the light emitting structure 171 and can be formed on the surface of the substrate 121, the light emitting structure 171 can be firmly fixed to the substrate 121 by the insulating layer 173.

Meanwhile, the light source 120 can comprise a connection electrode 174. The connection electrode 174 can serve as an intermediary connecting the electrode 150 and the semiconductor light emitting device 140. For example, the connection electrode 174 can extend from the electrode 150 and can contact a portion of the upper surface of the light emitting structure 171 via the side surface of the insulating layer 173 and the light emitting structure 171 disposed on the substrate 121. To this end, a portion of the insulating layer 173 disposed on the light emitting structure 171 can be removed to expose a portion of the upper surface of the light emitting structure 171, and the connection electrode 174 can be in contact with a portion of the upper surface of the exposed light emitting structure 171.

The connection electrode 174 can be made of a transparent conductive material, such as ITO, so as not to interfere with the emission of light, but is not limited thereto.

Although not shown, the connection electrode 174 can be formed on a portion of the inner side surface of the electrode 150 facing the side surface of the light emitting structure 171.

Meanwhile, as shown in FIG. 3, the electrode 150 can reflect light emitted from one side of the semiconductor light emitting device 140 so that it can be emitted in a specific direction. Accordingly, due to the change in shape of the semiconductor light emitting device 140, the light reflected by the electrode 150 can be added to the condensed light 125 emitted from the other side of the semiconductor light emitting device 140, so that even more intensely condensed light 125 can proceed at a specific beam angle θ11. For example, when the specific beam angle θ11 is 60 degrees with respect to the substrate 121, the condensed light 125 can be emitted from the semiconductor light emitting device 140 at a beam angle of 60 degrees.

In order to expand the light reflection area, the height of the electrode 150 (H in FIG. 4) can be increased. For example, the height of the electrode 150 can be greater than the height H of the semiconductor light emitting device 140. For example, the supper surface of the electrode 150 can be positioned higher than the upper surface (185 in FIG. 6A) of the semiconductor light emitting device 140.

However, if the height H of the electrode 150 is too high, the progress of the light 125 emitted in a specific direction from the semiconductor light emitting device 140 of the adjacent pixels 161 to 163 can be interrupted.

As shown in FIG. 5, a red semiconductor light emitting device 141 can be disposed in the first pixel 161, and a green semiconductor light emitting device 142 can be disposed in the second pixel 162 adjacent to the first pixel 161. In this case, the electrode 150_1 electrically connected to the red semiconductor light emitting device 141 can be disposed on one side of the red semiconductor light emitting device 141. The electrode 150_2 electrically connected to the green semiconductor light emitting device 142 can be disposed on the red semiconductor light emitting device 141 and the green semiconductor light emitting device 142. In other words, the red semiconductor light emitting device 141 and the electrode 150_1 can be disposed in the first pixel 161, and the green semiconductor light emitting device 142 and the electrode 150_2 can be disposed in the second pixel 162.

The condensed light 125 can be emitted from each of the red semiconductor light emitting device 141 and the green semiconductor light emitting device 142 at a specific beam angle θ11 with respect to the substrate 121. That is, the condensed light 125 can be emitted from each of the red semiconductor light emitting device 141 and the green semiconductor light emitting device 142 at a specific beam angle θ11, for example, in a diagonal direction between the right and upper sides.

For example, some light of the red semiconductor light emitting device 141 can be emitted directly from one side of the red semiconductor light emitting device 141 at a specific beam angle θ11, and other light of the red semiconductor light emitting device 141 can be emitted from the red semiconductor light emitting device 141 can be emitted from the other side, reflected by the electrode 150_1, and emitted at a specific beam angle θ11. In addition, some light of the green semiconductor light emitting device 142 can be emitted directly from one side of the green semiconductor light emitting device 142 at a specific beam angle θ11, and other light of the green semiconductor light emitting device 142 can be emitted from the other side of the green semiconductor light emitting device 142, reflected by the electrode 1502, and emitted at a specific beam angle θ11.

In this case, if the electrode 150_2 is too high, the condensed light 125 emitted from the red semiconductor light emitting device 141 is blocked by the electrode 150_2 and cannot proceed at a specific beam angle θ11.

To solve this problem, the height H of the electrode 150_2 must be lowered or the red semiconductor light emitting device 141 must be spaced further away from the electrode 150_2.

Since the first pixel 161 is fixed to a set size, the red semiconductor light emitting device 141 in the first pixel 161 cannot be spaced indefinitely away from the electrode 150_2. In addition, as the height H of the electrode 150_2 increases, the thickness of the light source 120 can become thicker.

Therefore, the red semiconductor light emitting device 141 can be optimally designed considering the separation distance from the electrode 150_2 and the height H of the electrode 150_2. For example, when the height H of the electrode 150_2 is determined, the separation distance L of the second pixel 162 of the red semiconductor light emitting device 141 from the electrode 150_2 can be expressed as Equation 1.

L=H/tan θ [Equation 1]

H: Height of electrode 150_2 of second pixel 162

θ: Beam angle of the light 125 emitted from the red semiconductor light emitting device 141

For convenience, the separation distance L of the red semiconductor light emitting device 141 can be expressed in Equation 1, but the separation distance L of the semiconductor light emitting devices 140 disposed in all pixels 161 to can be also expressed in Equation 1.

As shown in FIG. 4, the red semiconductor light emitting device 141 can be disposed closer to the electrode 150_1 than to the electrode 150_2 of the second pixel 162. For example, the red semiconductor light emitting device 141 can be disposed closer to the electrode 150_1 of the first pixel 161 than to the electrode 150_2 of the second pixel 162 from the center of the pixels 161 to 163. Therefore, since the red semiconductor light emitting device 141 is disposed close to the electrode 150_1, more light emitted from one side of the red semiconductor light emitting device 141 can be reflected by the electrode 1501, so that stronger condensed light 125 can be obtained. In addition, since the red semiconductor light emitting device 141 is disposed far from the electrode 150_2 of the second pixel 162, the condensed light 125 emitted from the other side of the red semiconductor light emitting device 141 at a specific beam angle θ11 may not be interrupted by the electrode 150_2 of the second pixel 162.

Meanwhile, the semiconductor light emitting device 140 of the embodiment can emit the condensed light 125 at a specific beam angle θ11. To this end, the shape of the semiconductor light emitting device 140 of the embodiment can be changed.

For example, as shown in FIGS. 6A and 6B, when the semiconductor light emitting device 140 of the embodiment has an isosceles triangle 180, the condensed light 125 having a specific beam angle θ11 can be obtained.

FIG. 6A is a perspective view illustrating a semiconductor light emitting device. FIG. 6B is a plan view illustrating a semiconductor light emitting device.

The isosceles triangle 180 can have a first-first side surface 181, a first-second side surface 182, a first-third side surface 183, an upper surface 185, and a lower surface, and the first-first side surface 181 and the first-second side surface 182 can have the same length. That is, the length of the first-first side 181 and the length of the first-second side 182 can be the same. In other words, the area of the first-first side 181 and the area of the first-second side 182 can be the same. Alternatively, the first-third side surface 183 can be different from the length of the first-first side surface 181 or the first-second side surface 182. In other words, the area of the first-third side surface 183 can be different from the area of the first-first side surface 181 or the first-second side surface 182.

In the semiconductor light emitting device 140 having this isosceles triangle 180, the light 125 can be emitted at a specific beam angle θ11 through the first-third side surface 183. That is, the light generated from the semiconductor light emitting device 140 having an isosceles triangle 180 can travel in all directions within the semiconductor light emitting device 140 and due to the isosceles triangle 180 that forms the outer shape of the semiconductor light emitting device 140, the condensed light 125 that light is condensed can be emitted through the first-third side surface 183 of the faces constituting the isosceles triangle 180.

The isosceles triangle 180 can have an apex angle θ21 between the first-first side surface 181 and the first-second side surface 182. For example, when the vertex angle θ21 is 90 to 150 degrees, the best condensed light 125 can be obtained. Preferably, the apex angle θ21 can be 120 degrees.

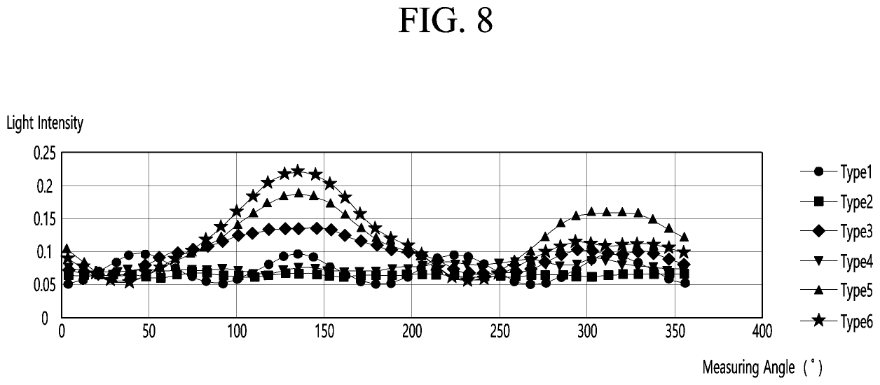

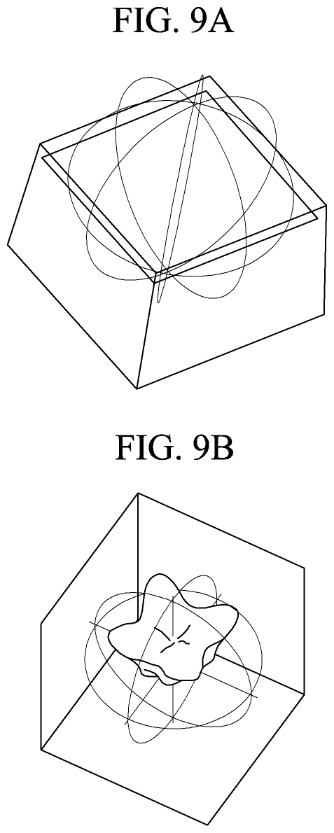

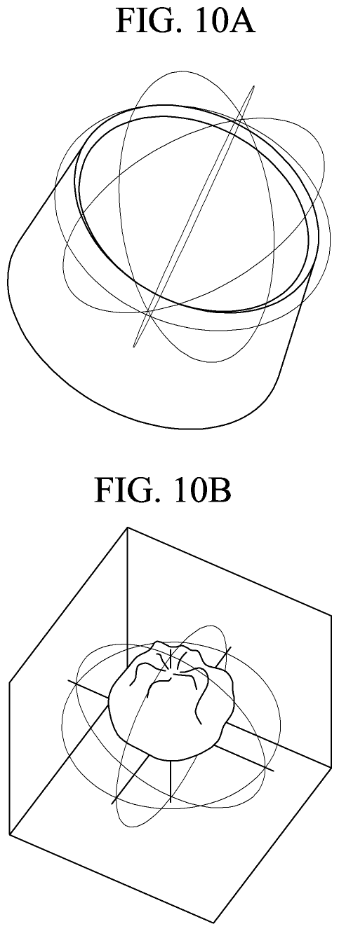

FIG. 8 illustrates the light intensity depending on the light measurement angle. FIGS. 9 to 14 illustrate light distribution according to the shape of the semiconductor light emitting device.

As shown in FIGS. 8 and 9, different light intensities are shown for various shapes of the semiconductor light emitting device.

FIGS. 9A and 9B illustrate a rectangular semiconductor light emitting device, which can be Type 1 in FIG. 8. In the case of a rectangular semiconductor light emitting device, as shown in FIG. 9B, it can be seen that light can be emitted in all directions, but weakly condensed light can be emitted in multiple directions.

FIGS. 10A and 10B illustrate a circular semiconductor light emitting device, which can be Type 2 in FIG. 8. In the case of a circular semiconductor light emitting device, as shown in FIG. 10B, it can be seen that light is emitted in all directions, but weakly condensed light is emitted mainly toward the front.

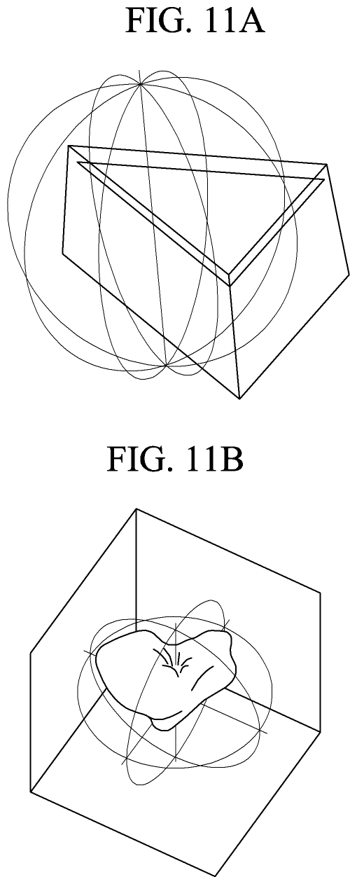

FIGS. 11A and 11B illustrate a semiconductor light emitting device having an isosceles triangle with a vertex angle of less than 50 degrees, which can be Type 3 in FIG. 8. In the case of a semiconductor light emitting device having an isosceles triangle with a vertex angle of less than 50 degrees, as shown in FIG. 11B, although condensed light is emitted in a specific direction, the condensed light can be weak.

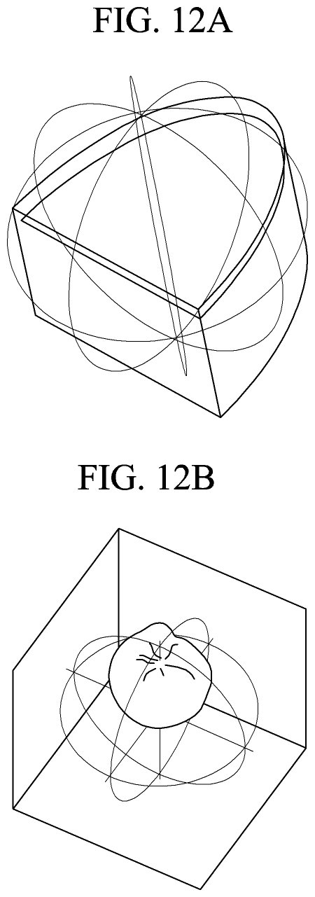

FIGS. 12A and 12B illustrate a semiconductor light emitting device having an isosceles triangle with a vertex angle of less than 90 degrees and the first-third side surface 183 having a round shape, which can be Type 4 in FIG. 8. In the case of a semiconductor light emitting device having an isosceles triangle and the first-third side surface 183 having a round shape, it can be seen that weakly condensed light can be emitted forward as shown in FIG. 12B.

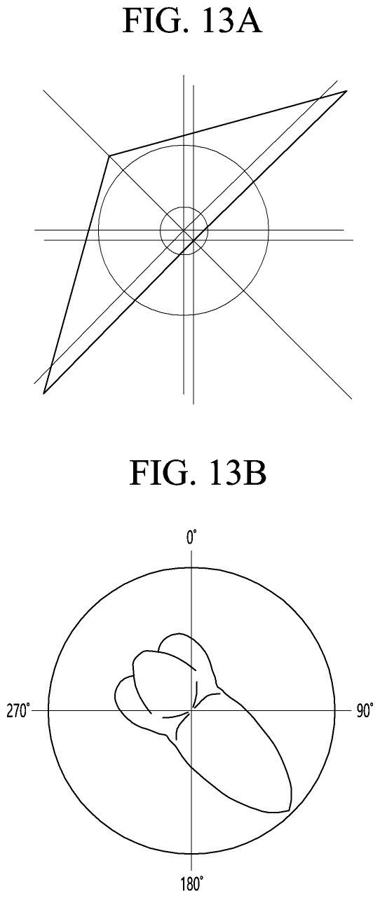

FIGS. 13A and 13B illustrate a semiconductor light emitting device having an isosceles triangle with a vertex angle of 120 degrees, which can be Type 5 in FIG. 8. In the case of a semiconductor light emitting device having an isosceles triangle with a vertex angle of 120 degrees, it can be seen that condensed light can be emitted in a specific direction.

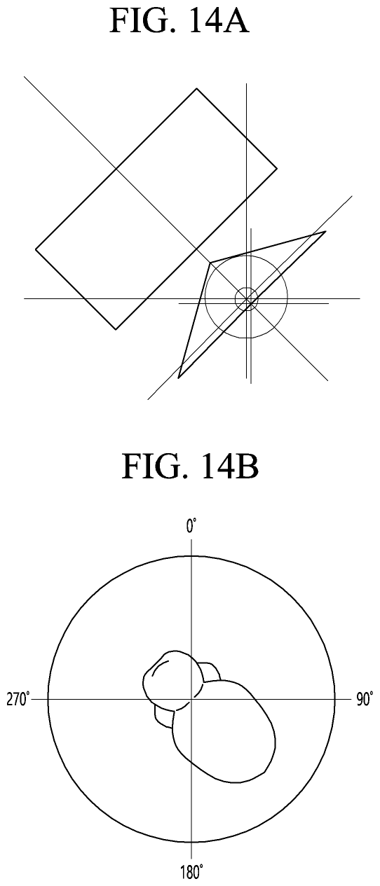

FIGS. 14A and 14B illustrate a case where a semiconductor light emitting device having an isosceles triangle with a vertex angle of 120 degrees and an electrode having a reflective function are disposed, which can be Type 6 in FIG. 8. When a semiconductor light emitting device having an isosceles triangle with a vertex angle of 120 degrees and an electrode with a reflective function are disposed, it can be seen that more condensed light can be emitted in a specific direction.

The results of measuring the light intensity emitted from various types of semiconductor light emitting devices (Typ1 to Type6) shown in FIGS. 9 to 14 while rotating 360 degrees in front of the semiconductor light emitting devices are shown in FIG. 8. As shown in FIGS. 13B and 14B, the light intensity of the semiconductor light emitting device was measured while rotating 360 degrees in front of the semiconductor light emitting device.

As shown in FIG. 8, it can be seen that Typ1, Type2, and Type4 have weak light intensity in all measurement directions.

In the case of Type3, it can be seen that the light intensity when measured at 135 degrees can be greater than that of each of Typ1, Type2, and Type4.

In contrast, it can be seen that the light intensity of Type 5 when measured at 135 degrees can be significantly greater than that of each of Type 1, Type 2, and Type 4. For example, it can be seen that when measuring at 135 degrees, the light intensity of each of Type 2 and Type 4 is approximately 0.051490685, while the light intensity of Type 5 is 0.1925, which is approximately 3.74 times greater.

Typ6 can have a light intensity of 0.220991949 when measured at 135 degrees, which is 4.29 times greater than the light intensity of type 2 and type 4, respectively.

Here, the beam angle at which the condensed light is emitted to the measurement area of 135 degrees with high light intensity can be determined. Type 5 and Type 6 each corresponds to the light source 120 of the embodiment, and as shown in FIGS. 6A and 6B, the condensed light can be emitted through the first-third side surface 183 of an isosceles triangle.

Therefore, as in the embodiment, through the combination of the semiconductor light emitting device 140 having an isosceles triangle 180 or the semiconductor light emitting device 140 having an isosceles triangle 180 and the electrode 150 having a reflective function, at least 4 times more light intensity can be obtained compared to before. That is, four times more condensed light can be emitted at a specific beam angle θ11 of the semiconductor light emitting device 140 of the embodiment. In this way, a significantly larger amount of condensed light is transmitted to the optical system 130 than before, so that a high-brightness image can be projected.

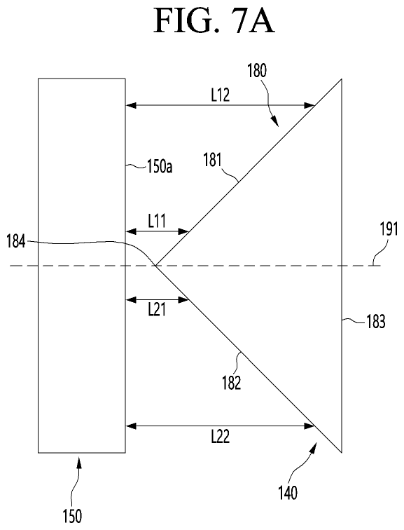

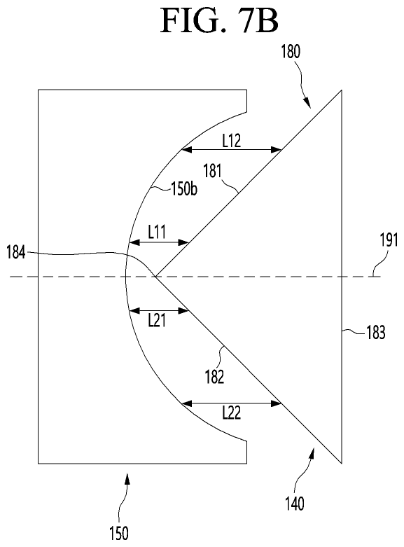

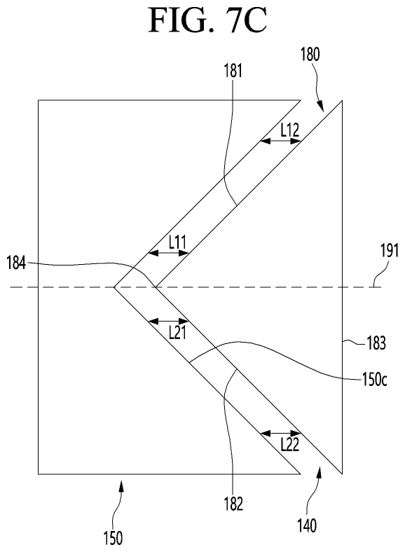

FIG. 7 illustrates the arrangement relationship between the electrode and the semiconductor light emitting device. FIG. 7 can be a top view of the electrode and the semiconductor light emitting device viewed from above.

As shown in FIG. 7A, an electrode and a semiconductor light emitting device 140 of an isosceles triangle 180 can be disposed in the pixels 161 to 163.

For example, the electrode 150 can have a rectangular shape, and the semiconductor light emitting device 140 can have an isosceles triangle 180. A center line 191 can be positioned across the center of the electrode 150. The isosceles triangle 180 can have a vertex point 184 where the first-first side surface 181 and the first-second side surface 182 meet. In this case, the vertex point 184 of the isosceles triangle 180 can be located on the center line 191 crossing the center of the electrode 150. For example, the vertex point 184 can be disposed closer to the electrode 150 than the first-third side surface 183. For example, the first-first side surface 181 and the first-second side surface 182 can be symmetrical to each other around the vertex point 184 of the isosceles triangle 180 located on the center line 191.

The semiconductor light emitting device 140 of the isosceles triangle 180 can be disposed to be spaced apart from the electrode 150. In this case, one side surface 150a of the electrode 150 can have a different separation distance from the entire surface of each of the first-first side surface 181 and the first-second side surface 182.

For example, the first side surface of the isosceles triangle 180 can become farther from the inner side surface 150a of the electrode 150 as the distance from the center line 191 increases. For example, the separation distance L12 between the second region on the first side surface far from the center line 191 and the second region on the inner side surface 150a of the electrode 150 can be greater than the separation distance L11 between the first region on the first side surface adjacent to the center line 191 and the first region of the inner side surface 150a of the electrode 150. The second side surface of the isosceles triangle 180 can become farther away from the inner side surface 150a of the electrode 150 as it moves away from the center line 191. For example, the separation distance L22 between the second region on the second side surface far from the center line 191 and the fourth region on the inner side surface 150a of the electrode 150 can be greater than the separation distance L21 between the first region on the second side adjacent to the center line 191 and the third region on the inner side surface 150a of the electrode 150.

As shown in FIG. 7B, an electrode 150 and a semiconductor light emitting device 140 of an isosceles triangle 180 can be disposed in the pixels 161 to 163. Since FIG. 7B is the same as FIG. 7A except for the shape of the electrode 150, the omitted description below can be easily understood from the description of FIG. 7A.

The inner side surface 150b of the electrode 150 can have a round shape with an inward depression.

The semiconductor light emitting device 140 of the isosceles triangle 180 can be disposed to be spaced apart from the electrode 150. In this case, one side surface 150b of the electrode 150 can have a different separation distance from the entire surface of each of the first-first side surface 181 and the first-second side surface 182.

For example, the first side surface of the isosceles triangle 180 can become farther from the inner side surface 150b of the electrode 150 as it moves away from the center line 191. For example, the separation distance L12 between the second region on the first side surface far from the center line 191 and the second region on the inner side surface 150b of the electrode 150 can be greater than the separation distance L11 between the first region of the first side surface adjacent to the center line 191 and the first region of the inner side surface 150b of the electrode 150. The second side surface of the isosceles triangle 180 can become farther away from the inner side surface 150b of the electrode 150 as it moves away from the center line 191. For example, the separation distance L22 between the second region on the second side surface far from the center line 191 and the fourth region on the inner side surface 150b of the electrode 150 can be greater than the separation distance L21 between the first region on the second side surface adjacent to the center line 191 and the third region on the inner side surface 150b of the electrode 150.

As shown in FIG. 7C, an electrode 150 and a semiconductor light emitting device 140 of an isosceles triangle 180 can be disposed in the pixels 161 to 163. Since FIG. 7C is the same as FIG. 7A or FIG. 7B except for the shape of the electrode 150, the omitted description below can be easily understood from the description of FIG. 7A or FIG. 7B.

The semiconductor light emitting device 140 can have an isosceles triangle 180, and the inner side surface 150c of the electrode 150 can have a shape corresponding to the isosceles triangle 180.

The semiconductor light emitting device 140 of the isosceles triangle 180 can be disposed to be spaced apart from the electrode 150. In this case, one side surface 150a of the electrode 150 can have the same separation distance from the entire surface of each of the first-first side surface 181 and the first-second side surface 182. That is, L11, L12, L21 and L22 can all be the same.

For example, the separation distance L11 between the first region on the first side surface adjacent to the center line 191 and the first region on the inner side surface 150c of the electrode 150 can be equal to the separation distance L12 between the second region on the first side surface far from the center line 191 and the second region on the inner side surface 150c of the electrode 150. For example, the separation distance L21 between the first region on the second side surface adjacent to the center line 191 and the third region on the inner side surface 150c of the electrode 150 can be equal to the separation distance L22 between the second region on the second side surface farthest from the center line 191 and the fourth region on the inner side surface 150c of the electrode 150.

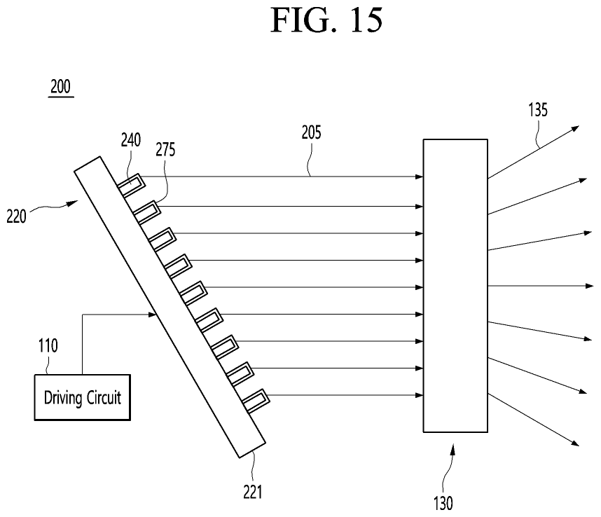

Meanwhile, a lens (275 in FIG. 15) that can adjust the emission direction or amount of light can be provided on the upper surface (185 in FIG. 6A) of the semiconductor light emitting device 140.

However, as the size of semiconductor light emitting devices decreased to the micro-level or nano-level, it was difficult to form a lens on the upper surface 185 of the semiconductor light emitting device, making it impossible to control the emission direction or amount of light using the lens.

The present applicant arranged the lens 275 to surround the semiconductor light emitting device 140 and changed the shape of the lens 275 to obtain light with a beam angle in a specific direction.

Hereinafter, a technology for emitting condensed light with a specific beam angle θ11 by combining the semiconductor light emitting device 140 and the lens 275 will be described in detail.

### The Second Embodiment

FIG. 15 illustrates an image projection device according to a second embodiment.

Referring to FIG. 15, the image projection device 200 according to the second embodiment can comprise a driving circuit 110, a light source 220, and an optical system 130. More elements can be provided.

Since the driving circuit 110 and the optical system 130 have been described in the first embodiment, detailed description is omitted.

In the following description, reference symbols for components not shown can be replaced with reference symbols for the same components described in the first embodiment.

In the light source 220 of the embodiment, a semiconductor light emitting device 240 and an electrode 150 can be disposed in each of the plurality of pixels 161 to 163.

A lens 275 can be disposed surrounding the semiconductor light emitting device 240 of the embodiment.

For example, the lens 275 can be disposed along the side surface (181 to 183 of FIG. 6A) of the semiconductor light emitting device 240. For example, the lens 275 can be disposed along the perimeter of the side surfaces 181 to 183 of the semiconductor light emitting device 240 and can also be disposed on the upper surface 185 of the semiconductor light emitting device 240.

The lens 275 can be made of a resin material, such as epoxy. For example, the lens 275 can be processed to have a groove in advance, and then the semiconductor light emitting device 240 can be inserted into the groove of the lens 275 to manufacture the semiconductor light emitting device 240 equipped with the lens 275. For example, a semiconductor light emitting device 240 equipped with a lens 275 can be manufactured by applying a resin material to surround the semiconductor light emitting device 240 and then curing it. In addition, the semiconductor light emitting device 240 equipped with the lens 275 can be manufactured through various processes.

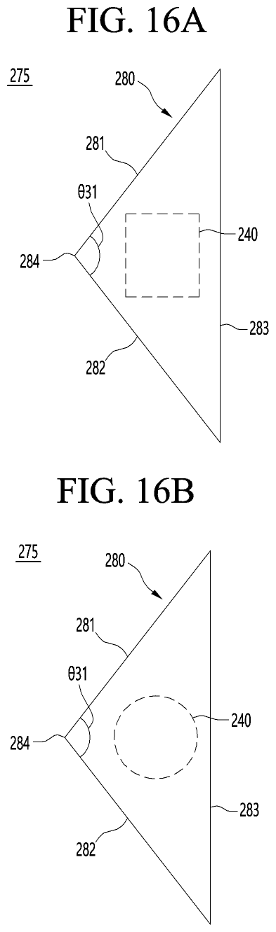

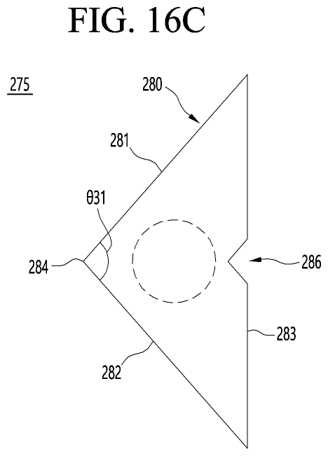

For example, each of the semiconductor light emitting device 240 and lens 275 can have various shapes. For example, the semiconductor light emitting device 240 can have various shapes, such as a square shape (FIG. 16A) or a circular shape (FIGS. 16B and 16C). For example, lens 275 can have an isosceles triangle (280 in FIGS. 16A, 16B, and 16C).

In an embodiment, the condensed light 205 having a specific beam angle θ11 can be emitted by the lens 275 surrounding the semiconductor light emitting device 240. In particular, as shown in FIG. 16C, the lens 275 can have an isosceles triangle 280, and an internally recessed recess 286 can be formed on the second-third side surface 283. Due to this recess 286, more condensed light 205 can be emitted through the second-third side surface 283.

The specific beam angle θ11 can be a beam angle inclined with respect to the substrate 121 and can coincide with a direction perpendicular to the optical system 130. The substrate 121 can be disposed to be inclined with respect to the optical system 130 so that the specific beam angle θ11 can proceed in a direction perpendicular to the optical system 130.

In an embodiment, the substrate 121 can be disposed to be inclined with respect to the optical system 130, thereby reducing the occupied area of the substrate 121 and reducing the volume of the light source 220.

Meanwhile, as shown in FIGS. 16A to 16C, in the isosceles triangle 280 of the lens 275, the length of the second-first side surface 281 and the length of the second-second side surface 282 are the same, and the length of the second-third side 283 can be different from the length of the second-first side surface 281 or the second-second side surface 282.

For example, the condensed light 205 emitted through the lens 275 can be emitted at an inclined beam angle with respect to the substrate 121 through the second-third side surface 283. For example, the isosceles triangle 280 of the lens 275 can have an apex angle θ31 between the second-first side surface 281 and the second-second side surface 282, and the apex angle θ31 can be 90 to 150 degrees.

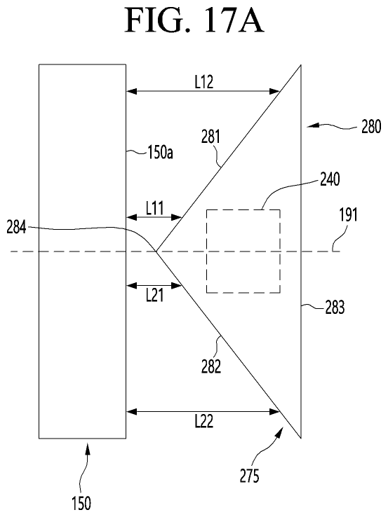

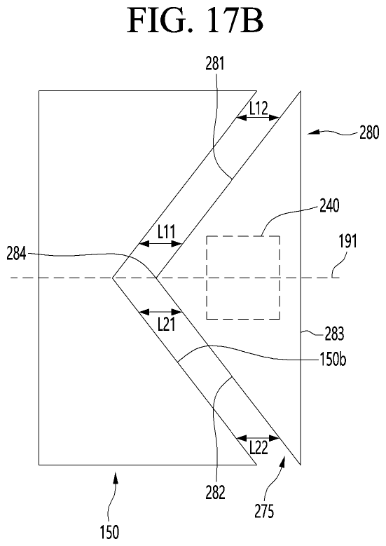

As shown in FIG. 17A, the electrode 150 can have a rectangular shape, and the semiconductor light emitting device 240 can have an isosceles triangle 280. For example, the inner side surface 150a of the electrode 150 can have a different separation distance from the entire surface of the second-first side surface 281 and the second-second side surface 282, respectively. That is, L12 can be greater than L11, and L22 can be greater than L21.

As shown in FIG. 17B, the semiconductor light emitting device 240 can have an isosceles triangle 280, and the inner side surface 150c of the electrode 150 can have a shape corresponding to the isosceles triangle 280. For example, the inner side surface 150b of the electrode 150 can have the same separation distance from each of the entire surfaces of the second-first side surface 281 and the second-second side surface 282. That is, L11 and L12 can be the same, and L21 and L22 can be the same.

For example, as shown in FIGS. 17A and 17B, the isosceles triangle 280 of the lens 275 can have a vertex point 284 where the second-first side 281 and the second-second side 282 meet, The vertex point 284 can be located on the center line 191 crossing the center of the electrode 150, and the vertex point 284 can be positioned closer to the electrode 150 than the second-third side surface 283.

Although not shown in FIG. 17, in addition to the lens 275 surrounding the semiconductor light emitting device 240, an electrode 150 having the shape shown in FIG. 7B can be disposed.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

### INDUSTRIAL APPLICABILITY

The image projection device of the embodiment can be applied to fields that can project images using light. For example, it can be applied to a television, a projection device in movie theater, an outdoor display signage, a portable beam projector, a HUD display in vehicle, an external information display device installed in vehicle, etc.

1. An image projection device, comprising:
a light source configured to output light corresponding to an image; and
an optical system disposed in front of the light source and configured to project the image,
wherein the light source comprises:
a substrate comprising a plurality of pixels; and
a plurality of semiconductor light emitting devices in the plurality of pixels of the substrate, respectively,
wherein the substrate is disposed to be inclined with respect to the optical system, and
wherein the semiconductor light emitting device is configured to emit a first condensed light having a first beam angle inclined with respect to the substrate.

2. The image projection device of claim 1, wherein the first condensed light emitted at the inclined first beam angle is configured to be perpendicularly incident on the optical system.

3. The image projection device of claim 1, wherein the light source comprises an electrode disposed on the substrate and spaced apart from the semiconductor light emitting device.

4. The image projection device of claim 3, wherein the semiconductor light emitting device has a first isosceles triangle having a first-first side surface, a first-second side surface and a first-third side surface, the first-first side surface and the first-second side surface having the same length, and the first-third side surface having a length different from the first-first side surface or the first-second side surface.

5. The image projection device of claim 4, wherein the first condensed light is configured to be emitted at the first beam angle inclined with respect to the substrate through the first-third side surface.

6. The image projection device of claim 4, wherein the first isosceles triangle has a first vertex angle between the first-first side surface and the first-second side surface, and
the first vertex angle is 90 degrees to 150 degrees.

7. The image projection device of claim 4, wherein the first isosceles triangle of the semiconductor light emitting device has a first vertex point where the first-first side surface and the first-second side surface meet,
the first vertex point is located on a center line crossing the center of the electrode, and
the first vertex point is located closer to the electrode than the first-third side surface.

8. The image projection device of claim 4, wherein one side surface of the electrode has a different separation distance from the entire surface of each of the first-first side surface and the first-second side surface.

9. The image projection device of claim 4, wherein one side surface of the electrode has the same separation distance from the entire surface of each of the first-first side surface and the first-second side surface.

10. The image projection device of claim 3, wherein the light source comprises a lens surrounding the semiconductor light emitting device, and
the lens is configured to emit a second condensed light having a second beam angle inclined with respect to the substrate.

11. The image projection device of claim 10, wherein the lens has a second isosceles triangle having a second-first side surface, a second-second side surface and a second-third side surface, the second-first side surface and the second-second side surface having the same length, and the second-third side surface having a length different from the second-first side surface or the second-second side surface.

12. The image projection device of claim 11, wherein the second condensed light is configured to be emitted at the second beam angle inclined with respect to the substrate through the second-third side surface.

13. The image projection device of claim 11, wherein the second isosceles triangle has a second vertex angle between the second-first side surface and the second-second side surface, and
the second vertex angle is 90 degrees to 150 degrees.

14. The image projection device of claim 11, wherein the second isosceles triangle of the lens has a second vertex point where the second-first side surface and the second-second side surface meet,
the second vertex point is located on a center line crossing the center of the electrode,
The second vertex point is located closer to the electrode than the first-third side surface.

15. The image projection device of claim 11, wherein one side surface of the electrode has a different separation distance from the entire surface of each of the second-first side surface and the second-second side surface.

16. The image projection device of claim 11, wherein one side surface of the electrode has the same separation distance from the entire surface of each of the second-first side surface and the second-second side surface.

17. The image projection device of claim 3, wherein the semiconductor light emitting device comprises a first semiconductor light emitting device and a second semiconductor light emitting device,
the electrode comprises a first electrode disposed on one side of the first semiconductor light emitting device and a second electrode disposed between the first semiconductor light emitting device and the second semiconductor light emitting device, and
the first semiconductor light emitting device is spaced apart from the second electrode by a distance L or more according to Equation 1.
L=H/tan θ [Equation 1]
H: Height of the second electrode
θ: Beam angle of condensed light emitted from the first semiconductor light emitting device

18. The image projection device of claim 1, wherein the light source comprises:
an insulating layer surrounding the semiconductor light emitting device; and
a connection electrode disposed on the insulating layer and configured to connect the electrode and the semiconductor light emitting device.

19. The image projection device of claim 1, wherein the semiconductor light emitting device has a side surface having an area larger than the area of an upper surface.

20. The image projection device of claim 1, wherein the semiconductor light emitting device comprises at least one or more of a red semiconductor light emitting device, a green semiconductor light emitting device, and a blue semiconductor light emitting device.
